(19) United States
(12) Patent Application Publication
(10) Pub. No.: US 2022/0193858 A1
(43) Pub. Date: Jun. 23, 2022

(54) ADAPTIVE SLURRY DISPENSE SYSTEM

(71) Applicant: Applied Materials, Inc., Santa Clara, CA (US)

(72) Inventors: Sameer DESHPANDE, Milpitas, CA (US); Sidney P. HUEY, Fremont, CA (US); Derek R. WITTY, Fremont, CA (US)

(21) Appl. No.: 17/554,596

(22) Filed: Dec. 17, 2021

Related U.S. Application Data
(60) Provisional application No. 63/127,433, filed on Dec. 18, 2020.

(51) Int. Cl. B24B 37/04; B24B 37/013; B24B 49/12; H01L 21/3105; H01L 21/768; H01L 21/66; G06N 20/00; G06K 9/62

(52) U.S. Cl. CPC B24B 37/042; B24B 37/013; B24B 49/12; G06K 9/6256; H01L 21/7684; H01L 22/26; G06N 20/00; H01L 21/31053

(57) ABSTRACT

Provided herein are advanced substrate polishing methods that use a machine-learning artificial intelligence (AI) algorithm, or a software application generated using the AI, to control one or more aspects of the polishing process. The AI algorithm is trained to simulate a polishing process and to make predictions about the polishing process and process results expected therefrom, using substrate processing data acquired from a polishing system.

### CROSS-REFERENCE TO RELATED APPLICATIONS

This application claims benefit of U.S. provisional patent application Ser. No. 63/127,433, filed Dec. 18, 2020, which is herein incorporated by reference.

### BACKGROUND

### Field

Embodiments described herein generally relate to semiconductor device manufacturing, particularly chemical mechanical polishing (CMP) systems used in semiconductor device manufacturing and related methods.

### Description of the Related Art

Chemical mechanical polishing (CMP) is commonly used to manufacture high-density integrated circuits to planarize a material layer on the substrate, to clear an excess of material from an underlying material layer surface, or both. In a typical CMP process, a substrate is retained in a carrier head that presses the backside of the substrate towards a rotating polishing pad in the presence of polishing fluid. The polishing pad is often formed of a polymer material with surface asperities that facilitate the transport of the polishing fluid to the interface between the substrate's material surface and the moving polishing pad disposed there beneath. The polishing fluid typically comprises an aqueous solution of one or more chemical components and nanoscale abrasive particles suspended in the aqueous solution, often referred to as a polishing slurry. Material is removed across the material layer surface of the substrate through a combination of chemical and mechanical activity, which is provided by the polishing fluid, the relative motion of the substrate and the polishing pad, and the contact pressure therebetween. Consumables, such as the polishing pad and the polishing fluid, are selected based on the desired CMP application.

Common CMP applications include bulk film planarization and removal of excess material in a damascene process. Planarization of a bulk film, such as interlayer dielectric (ILD) polishing, is typically used to smooth undesirable recesses and protrusions in the surface of a material layer that are caused by two or three-dimensional features disposed there beneath. Typical damascene CMP applications include shallow trench isolation (STI) and interlayer metal interconnect formation, where CMP is used to remove the trench, contact, via, or line fill material (overburden) from the exposed surface (field) of one or more underlying layers having the STI or metal interconnect features disposed therein.

Depending on the application, CMP process results are typically characterized by a combination of interrelated metrics related to global polishing uniformity, localized planarization performance, and CMP induced surface defectivity. Such process results can determine the performance, reliability, and/or operability of the resulting devices formed on the substrate. Process results outside of process tolerance limits may lead to device failure, thus suppressing the yield of usable devices formed on the substrate. Typically, process result tolerances are reduced with increasing circuit density and decreasing device feature size.

To meet industry demand for shrinking device geometries, advanced CMP systems have dramatically increased in complexity in order to provide control over virtually every processing variable (parameter) known to influence the process results. Such advanced CMP systems include highly engineered, and complex individual subsystems, each configured to control one or more processing parameters to a desired set point. The controllable processing parameters collectively define a substrate polishing recipe. Often, a polishing recipe for a single substrate CMP process comprises a multi-stage polishing sequence, where one or more parameter set points are changed for each stage of the sequence.

Unfortunately, advances in CMP technology have by far outpaced scientific understanding of the complicated interactions of chemical and mechanical activity between surfaces, fluids, and abrasives at the polishing interface. As a result, existing CMP models are generally unsuitable for use in process development. Thus, CMP substrate processes are typically determined and/or improved upon using conventional process development and improvement techniques. Examples of such techniques include design of experiments (DOE) and trial and error. Typically, standard quality control measures prohibit experimentation on production substrates having devices thereon that are intended for use or sale. As a result, DOE experiments are often performed using expensive test substrates while taking up valuable CMP processing system time. Thus, due to the time and costs associated therewith, it is virtually impossible to thoroughly explore the complicated relationships between polishing parameters, algorithms, consumables, device features, and processing results for the many individual polishing processes used in a production facility.

Thus, conventional process improvement methods are inadequate to take advantage of the combined capabilities of apparatus and subsystems of advanced CMP processing systems and are incapable of providing the improved processing results and wider process windows that might otherwise be realized therewith.

Accordingly, what is needed in the art are advanced processing methods that do not suffer from the disadvantages described above.

### SUMMARY

Embodiments of the present disclosure generally relate to chemical mechanical polishing (CMP) systems used in electronic device manufacturing, and more particularly, to advanced substrate processing methods for use therewith.

In one embodiment, a computer-implemented method of generating a substrate polishing recipe is provided. The method includes polishing a substrate using a polishing system, including (a) flowing a polishing fluid onto a surface of a polishing pad, according to a polishing recipe, the polishing recipe including a plurality of polishing parameters and a corresponding plurality of target values; (b) urging a substrate against the surface of the polishing pad according to the polishing recipe; (c) maintaining, by adjusting a first control parameter, a first polishing parameter of the plurality of polishing parameters at or near its target value; (d) generating processing system data including the polishing recipe and time-series data of the first control parameter; and (e) concurrently with (a)-(d), generating time-series in-situ results data using measurements obtained from an in-situ substrate monitoring system. The method further includes repeating (a)-(e) for a plurality of substrates to obtain a corresponding plurality of training data sets, each of the training data sets including the processing system data and the in-situ results data for a polished substrate; receiving, at an artificial intelligence (AI) training platform, training data including the plurality of training data sets; training a machine learning AI algorithm using the training data; and changing one or more of the plurality of polishing parameters using the trained machine learning AI algorithm.

In one embodiment, a computer-readable medium includes instructions for executing a method for determining a polishing recipe. The method includes receiving, at an artificial intelligence (AI) training platform, training data including a plurality of training data sets, where each of the training data sets includes processing system data and in-situ results data correlated to a substrate polished on a polishing system. The processing system data for each of the training data sets includes: a polishing recipe including a plurality of polishing parameters and a corresponding plurality of target values; and time-series data of a first control parameter used by a closed loop control system to maintain a first polishing parameter of the plurality of polishing parameter at or near the target value, and the in-situ results data for each of the training data sets includes time-series data generated using an in-situ substrate monitoring system. The method further includes training a machine learning AI algorithm using the training data; and determining, using the trained machine learning AI algorithm, a functional relationship between the in-situ results data and the time-series data for the first control parameter.

In one embodiment, a computer-implemented method of matching polishing performance between polishing systems is provided. The computer-implemented method includes receiving, at an artificial intelligence (AI) training platform, training data including a plurality of training data sets. Each of the training data sets includes processing system data correlated to individual ones of a first plurality of substrates polished using a first polishing system where different ones of the first plurality of substrates are polished using different combinations of substrate carrier assemblies from a plurality of substrate carrier assemblies and polishing stations from a plurality of polishing stations of the first polishing system. The processing system data for each of the training data sets includes: a polishing recipe including a plurality of polishing parameters and a corresponding plurality of target values, where one or more of the plurality of polishing parameters are maintained at or near their target value using corresponding closed-loop control system; and time-series data of control parameters of the closed-loop control systems. The method further includes training a machine learning AI algorithm using the training data. The trained machine learning AI algorithm is configured to identify differences between the different substrate carrier assemblies and/or the different polishing stations of the first polishing system. The method further includes implementing one or more corrective actions based on the identified differences.

Embodiments of disclosure will also provide a system of one or more computers that can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by a processor, cause the apparatus to perform the actions. One general aspect includes a computer-implemented method for polishing a substrate within one or more polishing systems. The computer-implemented method may include: (a) flowing a polishing fluid onto a surface of a polishing pad, according to a polishing recipe, the polishing recipe may include a plurality of polishing parameters and a corresponding plurality of target values; (b) urging a substrate against the surface of the polishing pad according to the polishing recipe; (c) maintaining, by adjusting a first control parameter, a first polishing parameter of the plurality of polishing parameters at or near its target value; (d) generating processing system data may include the polishing recipe and time-series data of the first control parameter; and (e) concurrently with (a)-(d), generating time-series in-situ results data using measurements obtained from an in-situ substrate monitoring system; repeating (a)-(e) for a plurality of substrates to obtain a corresponding plurality of training data sets, each of the training data sets may include the processing system data and the in-situ results data for a polished substrate; receiving, at an artificial intelligence (AI) training platform, training data may include the plurality of training data sets, where each of the plurality of training data sets are received sequentially in time; and changing one or more of the plurality of polishing parameters based on an analysis performed by a trained machine learning AI algorithm. Other embodiments of this aspect include corresponding computer systems, apparatus, and computer programs recorded on one or more computer storage devices, each configured to perform the actions of the methods.

Embodiments of disclosure will also provide a computer-implemented method for polishing a substrate within one or more polishing systems. The computer-implemented method may include: (a) flowing a polishing fluid onto a surface of a polishing pad, according to a polishing recipe, the polishing recipe may include a plurality of polishing parameters and a corresponding plurality of target values; (b) urging a substrate against the surface of the polishing pad according to the polishing recipe; (c) maintaining, by adjusting a first control parameter, a first polishing parameter of the plurality of polishing parameters at or near its target value; (d) generating processing system data may include the polishing recipe and time-series data of the first control parameter; and (e) concurrently with (a)-(d), generating time-series in-situ results data using measurements obtained from an in-situ substrate monitoring system; repeating (a)-(e) for a plurality of substrates to obtain a corresponding plurality of training data sets, each of the training data sets may include the processing system data and the in-situ results data for a polished substrate; receiving, at an artificial intelligence (AI) training platform, training data may include the plurality of training data sets, where at least a portion of the plurality of training data sets are received sequentially in time; and changing one or more of the plurality of polishing parameters based on an analysis performed by a machine learning AI algorithm.

Embodiments of disclosure will also provide a computer-implemented method of matching polishing performance between polishing systems, comprising receiving, at an artificial intelligence (AI) training platform, training data comprising a plurality of training data sets, wherein each of the training data sets comprises processing system data correlated to individual ones of a first plurality of substrates polished using a first polishing system, different ones of the first plurality of substrates are polished using different combinations of substrate carrier assemblies from a plurality of substrate carrier assemblies and polishing stations from a plurality of polishing stations of the first polishing system, and the processing system data for each of the training data sets comprises: a polishing recipe comprising a plurality of polishing parameters and a corresponding plurality of target values, wherein one or more of the plurality of polishing parameters are maintained at or near their target value using corresponding closed-loop control system; and time-series data of control parameters of the closed-loop control systems; and training a machine learning AI algorithm using the training data, wherein the trained machine learning AI algorithm is configured to identify differences between the different substrate carrier assemblies or the different polishing stations of the first polishing system; and implementing one or more corrective actions based on the identified differences.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic sectional view of a portion of a substrate which illustrates undesirably poor local planarization performance.

FIG. 1B is a schematic representation of a semiconductor device fabrication facility (Fab).

FIG. 1C is a schematic representation of a machine learning artificial intelligence (AI) training system, according to one embodiment, which may be used with the methods set forth herein.

FIG. 1D is a schematic representation of an exemplary closed-loop feedback control system which may be used with the polishing systems described herein.

FIG. 2A is a schematic side sectional view of an exemplary polishing system, according to one embodiment, which may be used to perform the methods set forth herein.

FIG. 2B is a schematic side sectional view of an exemplary substrate carrier.

FIG. 2C is a schematic side sectional view of the polishing system of FIG. 2A, shown from a different viewpoint.

FIG. 3 is a diagram illustrating a method of polishing a substrate, according to one embodiment.

FIGS. 4A-4C are schematic sectional views of a substrate illustrating different stages of a polishing process performed according to the methods set forth herein.

FIG. 5 is a diagram illustrating a method for matching performance between different polishing systems, according to one embodiment.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Embodiments of the present disclosure generally relate to chemical mechanical polishing (CMP) systems used in electronic device manufacturing, and more particularly, to advanced substrate processing methods for use therewith.

Generally, the advanced substrate processing methods herein use an algorithm, such as a machine learning artificial intelligence (AI) algorithm, or a software application generated using the AI algorithm, to control one or more aspects of the polishing process. In general, AI systems utilize large sets of data with intelligent, iterative processing algorithms to learn from patterns and features in the data that they analyze. Each time the AI system analyzes the data by performing a round of data processing, it will generally test and measure its own performance and develops additional expertise based on the analysis performed. Herein, the AI algorithm is trained to simulate a polishing process, to make predictions about the polishing process, and process results expected therefrom, using substrate processing data acquired from a polishing system.

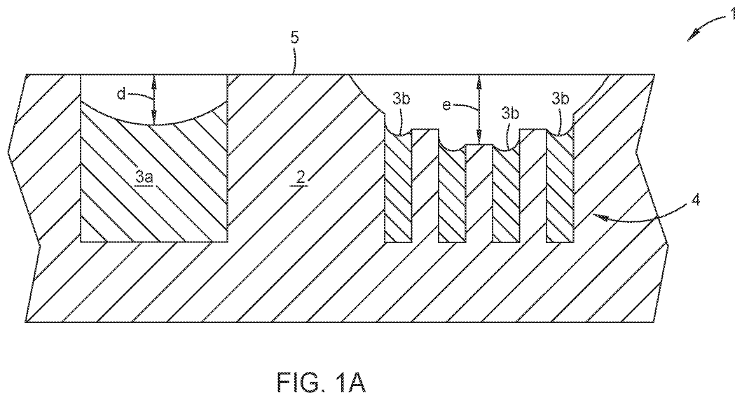

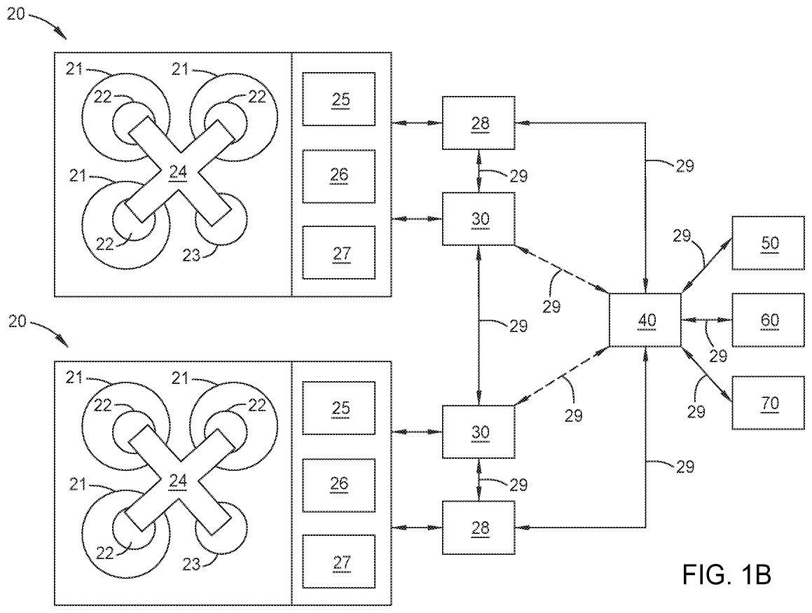

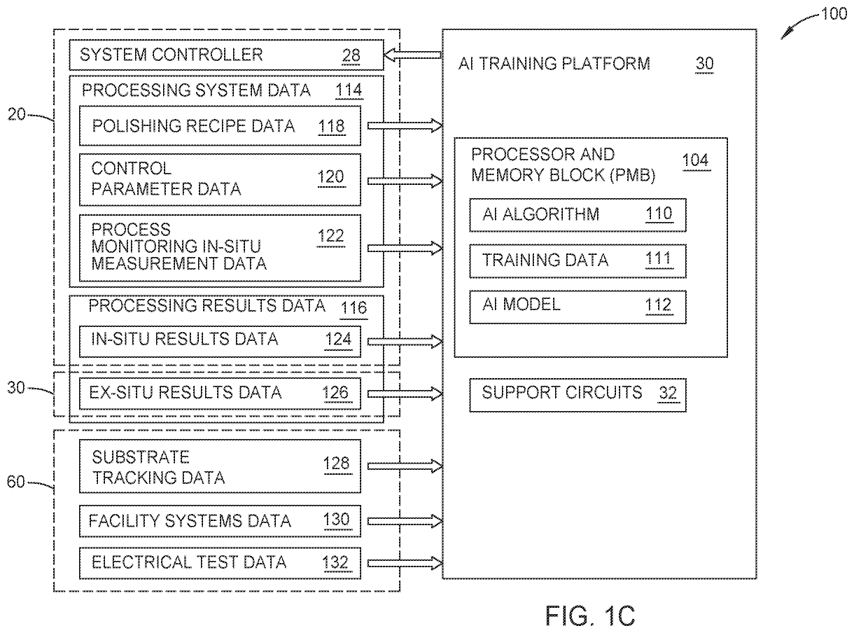

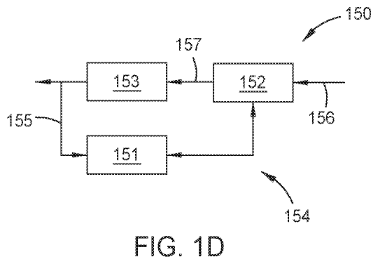

In some embodiments, the AI algorithm, or a software application generated using the AI algorithm, is used to predict a time horizon of a desired polishing endpoint and to adjust the composition of the polishing fluid thereon, e.g., by starting, stopping, or changing the flowrate of one or more polishing fluid components. As used herein, “polishing endpoint” denotes a point of time in the polishing process where it may be desirable to change one or more substrate polishing parameters, such as slurry composition, and does not necessarily denote an end to the polishing process. For damascene applications, the ability to accurately predict a desired polishing endpoint, and preemptively adjust a polishing fluid composition (e.g., slurry composition) based on the prediction, facilitates improved local planarization performance when compared to conventional reactive endpoint detection schemes. Improvements to local planarization performance result in desirable improvements in performance, reliability, and yield of resulting devices. An example of poor local planarization which may be improved using the methods provided herein is illustrated in FIG. 1A.

As is discussed further below, a polishing fluid composition (e.g., slurry composition) will generally include a mixture of one or more types of solid particles that are suspended in a liquid, such as water. The solid particles are often referred to as abrasives and can include metal oxide fine powders, such as CeO2, Fe2O3, Al2O3, and SiO2 that are suspended in a liquid. The liquid can include one or more of acids, bases and various additives (e.g., corrosion inhibitors, pH adjusting agents) that are often disposed within water.

FIG. 1A is a schematic sectional view illustrating poor local planarization, e.g., erosion to a distance e and dishing to a distance d, following a polishing process to remove an overburden of metal fill material from the field, i.e., upper or outer, surface of a substrate 1. Here, the substrate 1 features a dielectric layer 2, a first metal interconnect feature 3a formed in the dielectric layer 2, and a plurality second metal interconnect features 3b formed in the dielectric layer 2. The plurality of second metal interconnect features 3b are closely arranged to form a region 4 of relatively high feature density. Typically, the metal interconnect features 3a,b are formed by depositing a metal fill material onto the dielectric layer 2 and into corresponding openings formed therein. The material surface of the substrate 1 is then planarized using a CMP process to remove the overburden of fill material from the field surface 5 of the dielectric layer 2.

As shown, the poor local planarization performance has resulted in the recessing of an upper surface of the metal interconnect feature 3a from the surrounding surfaces of the dielectric layer 2 by a distance d, otherwise known as dishing. The poor local planarization performance has also resulted in undesirable recessing of the dielectric layer 2 in the high feature density region 4, e.g., distance e, where the upper surfaces of the dielectric layer 2 in the region 4 are recessed from the plane of the field surface 5, otherwise known as erosion. Metal loss resulting from dishing and/or erosion can cause undesirable variation in the effective resistance of the metal interconnect features 3a,b formed therefrom thus affecting device performance and reliability.

In some embodiments, the AI algorithm is trained using data from one or more polishing systems operating in a production capacity, i.e., in a semiconductor device fabrication facility. Training the AI algorithm using production polishing systems advantageously provides an abundance of data which may be used, by the AI algorithm, to better understand the complex relationships between the many variables of a particular polishing application. An exemplary fabrication facility (Fab) 10 is schematically illustrated in FIG. 1B.

Here, the Fab 10 includes a plurality of polishing systems 20, one or more machine learning artificial intelligence (AI) algorithm (hereafter “AI”) training platforms 30, a Fab production control system 40, one more stand-alone substrate inspection and/or metrology stations 50, and other processing systems 60. Other processing systems 60 include substrate processing systems used in the fabrication of semiconductor device which are found both upstream and downstream of the polishing process in the substrate process flow, such as epitaxy systems, thermal processing systems, non-epitaxy deposition systems, lithography systems, etch systems, implant systems, and other polishing systems. In some embodiments, the Fab 10 further includes one or more electrical test systems 70, such as parametric test and/or device yield test systems in communication with the Fab production control system 40.

Typically, each of the polishing systems 20 includes a plurality of polishing stations 21, a plurality of substrate carrier assemblies 22, a carrier loading station 23 for transferring substrates to and from the carrier assemblies 22, and a carrier transport system 24, for moving the substrate carrier assemblies 22 between the carrier loading station 23 and the different polishing stations 21. Here, each of the polishing systems 20 further includes one or more substrate inspection systems 25, one or more metrology systems 26, and a cleaning system 27 which are integrated with the polishing systems 20 to respectively perform pre and/or post polishing (in-line) inspections, measurements, and cleaning of substrates polished therein. Each of the polishing systems 20 includes a system controller 28 which directs and coordinates the operation of the various components and subsystems thereof.

As shown, each of the AI training platforms 30 is communicatively coupled to the corresponding system controller 28 using a communication link 29, such as an Ethernet or USB connection. In other embodiments, one or more for the AI training platforms 30 may be integrated with the system controller 28 to form a portion thereof. In some embodiments, the AI training platforms 30 are in direct communication with one or more components or subsystems of the polishing system 20. In some embodiments, an individual AI training platform 30 may be used with more than one polishing system 20 to perform the methods set forth herein and/or the individual AI training platforms 30 are communicatively coupled to one another to share training data 111 (FIG. 1C) therebetween. The training data 111 can be shared between the individual AI training platforms 30 at multiple different times. In one example, the training data 111 can be shared sequentially in time which can include shared at regular intervals of time or during or after one or more sequentially performed processes are run within a polishing system 20 and/or one or more asynchronous processes that are run in multiple polishing systems 20. In other embodiments, one or more of the AI training platforms 30 are not physically disposed in the Fab 10 and the methods described herein are implemented using cloud computing techniques.

The Fab production control system 40 directs the flow and processing of substrates as they travel through the production line and collects and manages data related to both the substrates and processing systems. Typically, the system controllers 28 are in communication with the Fab production control system 40 which provides instructions to the system controllers 28 and receives information therefrom. Here, the Fab production control system 40 is in further communication with the one or more stand-alone substrate inspection and/or metrology stations 50, other processing systems 60, and one or more electrical test systems 70. In some embodiments, the Fab production control system 40 communicates information received from the stand-alone substrate inspection and/or metrology stations 50, other processing systems 60, and one or more electrical test systems 70 to the system controllers 28 to be used as training data 111 (FIG. 1C) by the AI training platforms 30. In some embodiments, the Fab production control system 40 is in direction communication with the AI training platforms 30 through corresponding communication links 29. The communication links 29 can include conventional wired or wireless type of communication links.

FIG. 1C is a schematic representation of a process improvement scheme 100 which may be used with the methods set forth herein. The process improvement scheme 100 uses an AI training platform 30 which includes a processor and memory block (PMB 104) that is operable with support circuits 32 to execute a machine learning AI algorithm, herein the AI algorithm 110. The processor (not shown separately) of the PMB 104 is one or a combination of computer processors suitable for executing the AI algorithm 110, such as one or more of a programmable central processing unit (CPU), graphics processing unit (GPU), field programmable gate array (FPGA), machine learning application-specific integrated circuit (ASIC), or other suitable hardware implementation(s). The memory (not shown separately) of the PMB 104 is operably coupled to the processor, is non-transitory, and represents any non-volatile type of memory of a size suitable for storing the AI algorithm 110, the training data 111 to be used therewith, and one or more machine learning AI models 112 generated using the AI algorithm 110. The support circuits 32 are conventionally coupled to the processing unit and comprise cache, clock circuits, input/output subsystems, power supplies, and the like, and combinations thereof.

Here, the AI algorithm 110 is trained with training data 111 stored in the memory of the PMB 104 using one or a combination of supervised and unsupervised learning models. In one example of a supervised learning model, the AI algorithm 110 may be trained to map input data, such as times-series data of an individual control parameter, to output data, such as an individual processing result, based on an example input-output pair which is provided by a user. In an example unsupervised learning model, the AI algorithm 110 may be trained to find patterns and relationships in training data 111 that is received over time with a minimum of user input. The training process can occur based on multiple data sets received from various in-situ or ex-situ sensors over an extended period of time.

In embodiments where the AI algorithm 110 comprises a supervised model, a support vector machine (SVM) may be used, a regression model, or any supervised learning model capable of receiving the training data 111 and providing a continuous output indicative or predictive of a processing result. In embodiments where the AI algorithm 110 comprises an unsupervised model, a neural network may be used, or any unsupervised learning model capable of receiving the training data 111 to train the AI algorithm 110 to provide clustered and classified output which is indicative and/or predictive of one or more processing results. In some embodiments, such as in embodiments where the training data comprises images of different components of the polishing system 20 and/or of substrates processed therein, the AI algorithm 110 may use a convolutional neural network.

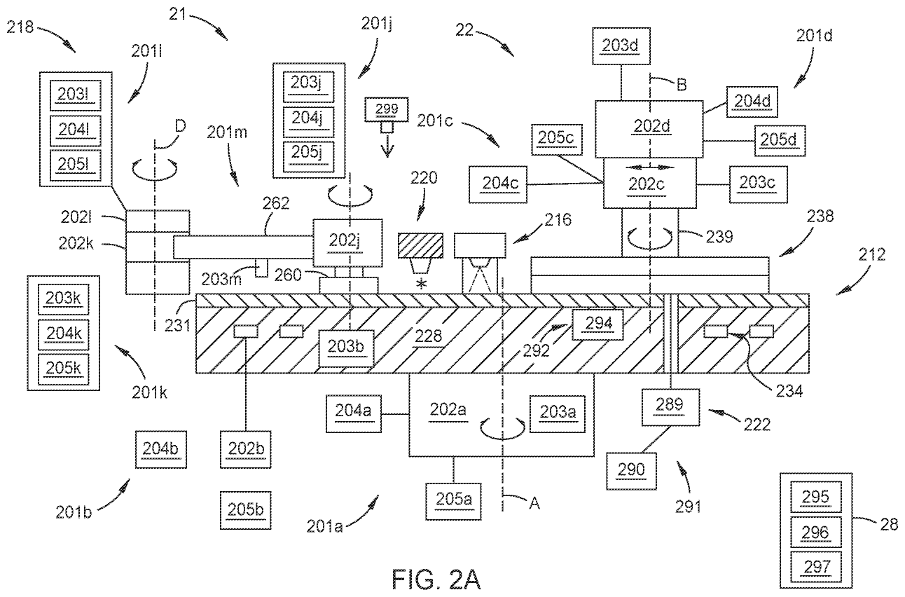

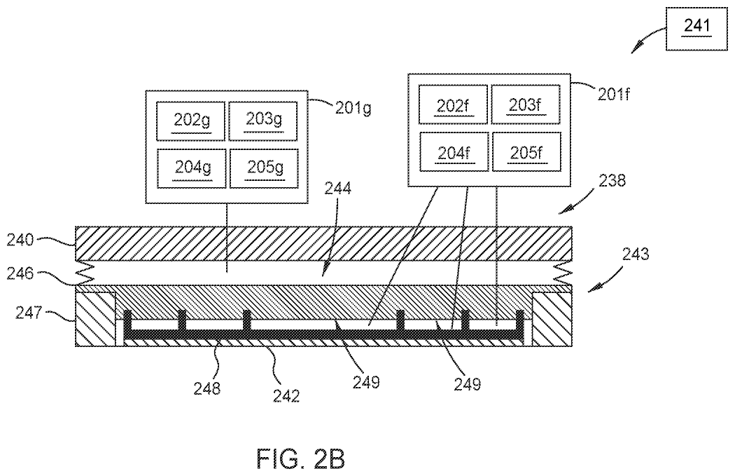

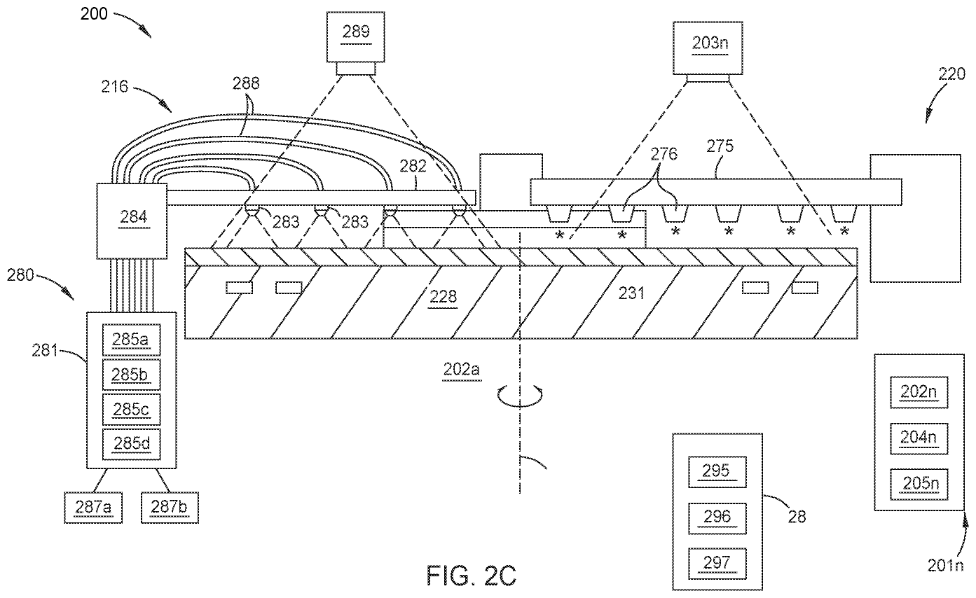

Herein, the training data 111 includes processing system data 114 generated by a polishing system 20, or subsystems thereof, and the corresponding processing results data 116 for one or more substrates processed on the polishing system 20. Here, the processing system data 114 used to train the AI algorithm 110 includes: polishing recipe parameter data 118, e.g., individual polishing parameters and target values corresponding thereto; control parameter data 120 provided by one or more parameter control systems 201a-n, such as described in FIGS. 2A-2C; and process monitoring data 122, e.g., generated by additional sensors or measurement devices disposed in a polishing system 20, that relates to the operation and processing performance of the subsystem and/or consumables thereof. The processing system data 114 generated by the polishing system 20, or subsystems thereof, may be represented by discrete values, such as those provided in a polishing recipe, or may be comprise time-series data, e.g., a series of data points (or images) arranged in time order.

In some embodiments, the AI training platform 30 is communicatively coupled to one or more components of the polishing system 20 and at least portions of the processing system data 114 are received therefrom. In some embodiments, at least portions of the processing system data 114 are stored in a memory of the polishing system controller 28 and the AI training platform 30 receives the processing system data 114 therefrom.

Processing results data 116 includes information related to planarization and/or removal of a material layer from the substrate during the polishing process which is obtained through measurements or inspection of the substrate, including information derived from measurements or inspection of the substrate. In some embodiments, processing results data 116 includes images taken of the surface of the substrate, e.g., by use of a camera device.

Here, processing results data 116 includes substrate measurements obtained concurrently with the polishing process, (in-situ results data 124), e.g., by use of an eddy current sensor or an optical sensor as described in FIG. 2A below, and substrate measurements taken subsequent to the polishing process (ex-situ results data 126). In some embodiments, the in-situ results data 124 comprises time series-data. In some embodiments, processing results data 116 includes differences between measurements obtained before the polishing process and measurements obtained thereafter, such as material removal rate or material removal uniformity.

Here, the in-situ results data 124 includes time-series eddy current information and/or time-series optical signal information obtained using an in-situ substrate monitoring system 222 described in FIG. 2A. The in-situ results data 124 typically includes the signal information and may include information derived from the signal information, such as material layer thickness and material layer uniformity information.

Ex-situ results data 126 may be generated using any suitable metrology or inspection systems typically found in a semiconductor device manufacturing facility. In some embodiments, at least portions of the ex-situ results data 126 are generated using one or more in-line inspection systems 25 and/or metrology systems 26 of the polishing system 20, and the portions of the ex-situ results data 126 is received at the AI training platform 30 therefrom. In some embodiments, at least portions of the ex-situ results data 126 are stored in the memory of the polishing system controller 28, which is communicatively coupled to the in-line systems 25, 26 and the AI training platform 30 receives the portions of the ex-situ results data 126 from the processing system controller 28.

In some embodiments, at least a portion of the ex-situ results data 126 is generated using one or more stand-alone inspection and/or metrology stations 50, which are separate from the polishing system 20. Typically, in those embodiments, the ex-situ results data 126 is collected and/or received from the Fab production control system 40 communicatively coupled to each of the stand-alone inspection and/or metrology stations 50.

Examples of information that may form a portion of the ex-situ results data 126 include: material removal rate (MRR); material layer planarization (global planarity); uniformity between substrates, i.e., wafer-to-wafer non-uniformity (WTWNU); uniformity of the material removal rate across the surface of the substrate and/or uniformity of the thickness of the planarized material layer, collectively within-wafer non-uniformity (WIWNU) metrics; planarization efficiency; local planarity, e.g., within-die (WID) planarity; undesired removal of an underlying material layer, e.g., oxide loss; erosion of the underlying material layer in regions of high feature density; recessing (dishing) of material in trench, contact, via and/or line features; and polishing induced defects at, or in, the substrate surface and/or in the exposed features formed therein. CMP induced defects include mechanical related defects, such as scratches, and chemical related defects, such as corrosion of a metal feature.

In some embodiments, the ex-situ results data 126 includes images obtained from in-line and/or stand-alone metrology and/or inspection systems, such as images of the substrate acquired with a camera device or other optical sensor. In some embodiments, the ex-situ results data includes images generated by metrology or inspection systems which represents information obtained from the substrate, e.g., material layer thickness, planarity, defectivity, and/or stress maps of the substrate and/or the substrate surface.

In some embodiments, the training data 111 includes one or more of substrate tracking data 128, facilities systems data 130, and electrical test data 132. Here, substrate tracking data 128 includes identifying information for the substrate, information related to devices formed on the substrate, and the processing history of the substrate. Examples of device information include device size, device geometries, feature size, and pattern density. Processing history typically includes identification of upstream processing systems and corresponding processing information such as day/time information and processing recipes used therewith. Processing history may also include information obtained from upstream metrology and/or inspection systems.

Facilities systems data 130 includes information related to facilities supply systems coupled to the polishing system 20 and/or environmental conditions surrounding the polishing system 20, e.g., temperature, particle count, and airflow. Examples of information related to facilities supply systems includes information obtained from deionized (DI) water supply systems, clean dry air (CDA) supply systems, chemical delivery systems, and remote polishing fluid distribution systems. Typically, remote polishing distribution systems circulate polishing fluids through facilities lines for delivery to a plurality of polishing systems 20 fluidly coupled to the facilities lines at the point of use. Such polishing fluid distribution systems are often configured for bulk mixing of polishing fluids and may include one or more analyzers to facilitate the mixing process and/or for continuous monitoring of polishing fluid health. Monitoring of the polishing fluid health includes using the analyzers to determine and monitor the polishing fluids chemical properties (e.g., pH and oxidizer and additive levels and their decay behavior) as well as abrasive properties of the polishing fluid, including Large Particle counts (LPC), mean Particle Size Distribution (PSD), density, weight percentage of solids, and viscosity. Information related to facilities systems, including polishing fluid health may be communicated to the individual system controllers 28 of the plurality of polishing systems 20 and/or to the fab production control system 40 and received by the AI training platforms 30 therefrom.

Electrical test data 132 may include parametric test information, generated at a subsequent parametric test operation, e.g., using dedicated test structures disposed in dice lines between devices, and/or device test information, generated at one or more subsequent device testing operations. In some embodiments, the electrical test data 132 includes images representing information obtained during the parametric and/or device testing operations, such as device yield maps representing the location on a substrate of operable and failing devices.

Here, the training data 111 includes identifying information, such as substrate tracking information, system information, and timestamp information which may be used to correlate information received from each the above described data sources to a particular substrate, polishing system, polishing station, and substrate carrier combination which forms a set of training data corresponding thereto.

In some embodiments, the trained AI algorithm 110 is used to generate an AI model 112, e.g., a software algorithm, which is communicated to the system controller 28 to be used as instructions to direct the operation of the polishing system 20.

FIG. 1D is a schematic representation of a control system 150 which may be used to generate the control parameter data 120. The control parameter data 120 comprises time-series data of one or more control parameters 157 used, by the control system 150, to maintain a polishing parameter at or near a target value 156. As used herein, a “target value” includes a desired set point, values above a desired lower threshold, values below a desired upper threshold, and values between desired lower and upper thresholds.

In FIG. 1D, the process control system 150 provides a closed feedback control loop for maintaining a polishing parameter at or near the target value 156. As shown, the process control system 150 includes a sensor 151, a controller 152, and a parameter control device 153, such as an actuator, operably coupled to the controller 152. Here, the sensor 151, the controller 152, and the control device 153 are arranged with information flowing in the feedback loop 154 to provide a closed-loop feedback control system.

During a polishing process, the sensor 151 measures an actual value 155 of a polishing parameter, (e.g., platen rotational speed, polishing fluid flow rate, etc.), and the controller 152 determines an error between the actual value 155 and the target value 156. To correct the error, the controller 152 instructs the parameter control device 153, (e.g., an actuator (motor) coupled to the platen, slurry dispense pump connected to a slurry delivery system, etc.), to change a control parameter 157, (e.g., motor current, pump pressure, pump speed, etc.), which causes a corresponding change in the polishing parameter output (e.g., platen rotational speed, slurry flow rate, etc.).

The parameter control system 150 is generally reactive such that, once a polishing parameter has ramped up to reach the target value 156, changes to a control parameter 157 by the controller 152, indicate a response to a change in the polishing process. Similarly, changes in a control parameter 157 from substrate-to-substrate for substantially similar polishing processes may be indicative of undesirable process drift. Thus, in embodiments herein, time-series control parameter data 120 is included in the processing system data 114 to enable the AI algorithm 110 to better understand the complex relationships between subsystems, processing parameters, consumables, and substrates for a particular polishing process.

FIG. 2A is a schematic side sectional view of a polishing station 21 and carrier assembly 22, according to one embodiment, which may be used with the methods set forth herein. Here, the polishing station 21 includes a plurality of subsystems each operable with one or a combination of parameter control systems 201a-n. Herein, each of the parameter control systems 201a-n is configured to include a closed feedback control loop and may include any one or combination of the elements of the process control system 150 described in FIG. 1D.

Typically, each of the control systems 201a-n includes one or more corresponding actuators 202a-n, processing parameter sensors 203a-n, controllers 204a-n, and control parameter sensors 205a-n. The actuators 202a-n include any device or process system operable to change a control parameter in response to a signal, such as an electrical, pneumatic, or a digital signal, received from the controller 204a-n. Examples of common actuators 202a-n include, but are not limited to, electromechanical devices, electromagnetic devices, pneumatic devices, hydraulic devices, and combinations thereof such as motors, servos, solenoids, valves, pumps, pistons, and regulators.

Processing parameter sensors 203a-n include any devices or combination of devices, which may be used to measure a value of a processing parameter or may be used to provide one or more measurements where an actual value of a desired processing parameter may be determined therefrom. Examples of suitable processing parameter sensors 203a-n include temperature sensors, e.g., IR sensors, pyrometers, and thermocouples, pressure sensors, force sensors, position sensors, acceleration sensors, rotations speed sensors, rotary encoders, electrical signal detecting sensors, electrochemical sensors, pH sensors, concentration sensors, optical sensors, induction sensors, flow sensors (mass and/or volume), and combinations thereof.

Controllers 204a-n comprise devices or systems operable to determine a difference between an actual value of a processing parameter and a target value of the processing parameter, i.e., the error, and to instruct a corresponding actuator 202a-n or processing system to change an output thereof, e.g., the control parameters described herein. Examples of suitable controllers 204a-n include proportional-integral (PI) controllers, proportional-integral-derivative (PID) controllers, and/or logic controllers, e.g., programmable logic controllers (PLCs) which have been programmed to execute a software comprising a logic application. In some embodiments, such as when the control parameter comprises an output of a processing system, the system controller 28 or another computing device operable to execute a software algorithm may be used as a controller 204a-n. In some embodiments, one or more of the functions of an individual or combination of controllers 204a-n may be performed by the system controller 28.

The control parameter sensors 205a-n include any sensor suitable for measuring an output of an actuator 202a-n or process system, which is used to maintain a processing parameter at a target value. Examples of suitable sensors which may be used as the control parameter sensors 205a-n include any one or combination of the example sensors described above with respect to the processing parameter sensors 203a-n. In some embodiments, such as for control systems where measuring the control parameter is not feasible, the control parameter or an approximation thereof, may be determined using the signal and/or instructions provided by a controller 204a-n to a corresponding actuator 202a-n or processing system.

In other embodiments, any one or combination of the individual subsystems described below may operate using an open-loop control system, i.e., a non-feedback system.

Herein, a plurality of subsystems include a platen assembly 212, the carrier assembly 22, a pad conditioner assembly 218, and a pad cooling assembly 220. The polishing station 21 further includes a fluid delivery system 216, and the in-situ substrate monitoring system 222. Operation of the polishing station 21 and carrier assembly 22 is coordinated by the system controller 28.

The platen assembly 212 includes a platen 228 and a rotation speed control system 201a. The control system 201a includes a platen actuator 202a, e.g., a motor, which is coupled to the platen 228 and is used to rotate the platen 228 about a platen axis A, a process parameter sensor 203a used to measure the rotational speed and/or rotational orientation of the platen 228, a controller 204a, and control parameter sensor 205a.

Here, the controller 204a, in combination with the sensor 203a, maintains the rotational speed of the platen 228 at or near a target value by adjusting a control parameter, such as motor current, provided to the platen actuator 202a. The control parameter sensor 205a is used to measure the control parameter and time-series control parameter data is generated therefrom. In some embodiments, changes in the control parameter of the motor current are caused by changes in friction between surfaces at the polishing interface as an overburden of material is cleared from a field surface of a substrate 242 (FIG. 2B) urged thereagainst. Thus, in some embodiments changes in the motor current may be used to detect a desired polishing endpoint of a polishing process. In other embodiments, the motor current may be used to detect variations in the amount of slurry delivered to the polishing pad and surface of the substrate 242 at any instant in time during polishing. For example, a higher friction sensed by the motor current may be caused by a drop in slurry flow or change in the composition of the slurry composition.

The platen assembly 212 further includes a platen temperature control system 201b comprising a fluid source 202b, e.g., water or a refrigerant source, a sensor 203b to measure a temperature of the platen 228, and a controller 204b. The temperature of platen may be used to detect variations in the amount of slurry delivered to the polishing pad, variations in polishing pad properties (e.g., amount of glazing), or variations in downforce applied to the substrate 242 at any instant in time during polishing. The platen 228 is formed of a cylindrical metal body having one or more channels 234 formed therein. The one or more channels 234 are fluidly coupled to the fluid source 202b. The controller 204b, in combination with the sensor 203b, is used to maintain the temperature of the platen 228 at a target value by adjusting a flowrate of a coolant from the fluid source 202b through the one or more channels 234. In some embodiments, the control parameter(s) for controlling the temperature of the polishing platen 228 comprises the coolant flowrate measured by a flowmeter, e.g., the control parameter sensor 205b. For some polishing processes it may be desirable to heat the platen 228, in those embodiments the fluid source 202b may comprise a heated fluid, e.g., heated water and/or steam, and the target value may comprise temperatures above a lower threshold. In some embodiments, the platen 228 is heated using a heater (not shown), such as a resistive heating element disposed and/or embedded in the cylindrical metal body.

The carrier assembly 22 includes a substrate carrier 238, a carrier shaft 239, and control systems 201c,d. The substrate carrier 238 is described below in FIG. 2B. The control system 201c includes a first actuator 202c, a controller 204c, a rotational speed sensor 203c, and a control parameter sensor 205c. The first actuator 202c is coupled to the carrier shaft 239 and is used to rotate the carrier shaft 239, and thus the substrate carrier 238 and the substrate 242 disposed therein, about a carrier axis B. The controller 204c, in combination with the sensor 205c, is used to maintain the rotational speed of the substrate carrier 238 at or near a target value by adjusting a control parameter, such as motor current, provided to the first actuator 202c. The control parameter sensor 205c is used to measure the control parameter provided to the first actuator 202c.

The control system 201d includes a second actuator 202d coupled to the carrier shaft 239 and/or the first actuator 202c, a controller 204d, a sweep speed sensor 203d, and a control parameter sensor 205d. The controller 204d, in combination with the sensor 203d, is used to maintain the sweep speed of the substrate carrier 238 at or near a target value by adjusting a control parameter, such as motor current, provided to the second actuator 202d. The control parameter sensor 205d is used to measure the control parameter provided to the second actuator 202d.

As shown in FIG. 2B, the substrate carrier 238 includes a housing 240, a base assembly 243, a substrate downforce control system 201f, and a carrier load control system 201g. The housing 240 is movably and sealingly coupled to the base assembly 243 to define a loading chamber 244 therewith. The base assembly 243 includes a carrier base 246, an annular retaining ring 247 coupled to the carrier base 246, and a flexible membrane 248 coupled to the carrier base 246 to define a plurality of plenums 249 therewith.

During substrate polishing, the plurality of plenums 249 are pressurized causing the flexible membrane 248 to exert a force against a non-active (backside) surface of the substrate 242 therebeneath. The plurality of plenums 249 facilitate adjustments to the distribution of forces exerted across the backside surface of the substrate 242 by allowing for differences in pressures therein. The pressures in the different plenums 249 and the difference in pressures therebetween are maintained by the control system 201f which includes a plurality of actuators 202f (e.g., backside pressure regulators, valves, etc.), a plurality of sensors 203f, one or more controllers 204f, and one or more control parameter sensors 205f. The control system 201f is used to maintain target pressures in each of the plenums 249 allowing for fine control over the distribution of force exerted by the flexible membrane 248 against the substrate 242.

The one or more controllers 204f, in combination with the plurality of sensors 203f, maintain the pressures in the plenums 249 at their target values by adjusting respective control parameters to the corresponding actuators 202f thereof. The different control parameter values are measured by control parameter sensors 205f corresponding thereto.

During processing, the loading chamber 244 is also pressurized in order to exert a downward force against the carrier base 246, and thus the retaining ring 247 which surrounds the substrate 242. The downward force on the retaining ring 247 prevents the substrate 242 from slipping from the substrate carrier 238 as the polishing pad 231 (FIG. 2A) moves therebeneath. The contact pressure between the retaining ring 247 and the polishing pad 231 is adjusted by changing a target downforce on the retaining ring 247. The target downforce is maintained by the control system 201g which includes an actuator 202g, e.g., a backside pressure regulator, a sensor 203g for measuring the pressure in the load chamber 244 and/or a contact load between the retaining ring 247 and the polishing pad 231, a controller 204g for maintaining target pressures in the loading chamber 244, and a control parameter sensor 205g. The controller 204g, in combination with the sensor 203g, maintains the pressure in the load chamber 244 at or near its target value by adjusting a control parameter provided to the actuator 202g. Here, various components of the control systems 201g,h collectivity form an upper pneumatic assembly, here the UPA 241, which may further include regulators, valves, and pumps (now shown) used to provide pressurized gas, e.g., clean dry air (CDA) and/or a vacuum, to the plurality of plenums 249 and the loading chamber 245. In other embodiments, electromechanical devices may be used to exert the downforces against one or both of the substrate 242 and the retaining ring 247.

The pad conditioner assembly 218 (FIG. 2A) is used to condition the polishing pad 231 by urging a conditioning disk 260 against the surface of the polishing pad 231 before, after, or during polishing of the substrate 242. Here, the pad conditioner assembly 218 includes the conditioning disk 260, a conditioner arm 262 for sweeping the rotating conditioning disk 260 between an inner radius and an outer radius of the polishing pad 231, and a plurality of control systems 201j-m for controlling various aspects of the pad conditioning process.

Typically, the conditioning disk 260 comprises a fixed abrasive conditioning surface, e.g., diamonds embedded in a metal alloy, and is used to abrade and rejuvenate the surface of polishing pad 231, and to remove polish byproducts or other debris therefrom. The conditioning disk 260 is generally considered a processing consumable requiring regular replacement as the abrasiveness of the conditioning disk 260 will naturally dull with use.

The control systems 201j,k are used to maintain the rotation speed and the sweep speed of the conditioning disk 260 at respective target values as the conditioning disk 260 is oscillated between the inner radius and the outer radius of the polishing pad 231. The control system 201l is used to maintain a downward force exerted on the conditioning disk 260 at a target value. In some embodiments, the pad conditioner assembly 218 further includes a control system 201m which may be used to provide and/or maintain a desired polishing pad thickness profile across the surface of the polishing pad 231. In those embodiments, a desired polishing pad thickness profile is maintained by adjusting one or a combination of the rotational speed, sweep speed and downforce according to instructions provided by a software algorithm executed by the system controller 28.

Here, the control system 201j includes a first actuator 202j coupled an end of the conditioner arm 262, where the first actuator 202j is used to rotate the conditioning disk 260 about an axis C, and a sensor 203j for determining the rotational speed, and a controller 204j.

The control system 201k includes a second actuator 202k coupled to an end of the conditioner arm 262 distal from the first actuator 202j, one or more sensors 203k for determining a sweep speed and or radial position of the conditioning disk 260 on the polishing pad, a controller 204k, and a control parameter sensor 205k. The control system 201g includes a third actuator 202l for exerting a downforce on the conditioner arm 262, a sensor 203l for measuring the downforce, a controller 204l, and a control parameter sensor 205l. Here, the third actuator 202l is coupled to an end of the conditioner arm 262 at a location proximate to the second actuator 202l and distal from the conditioning disk 260. Each of the controllers 204j-1, in combination with the corresponding sensors 203j-1, maintain the respective processing parameters at or near their target values by adjusting a control parameter of the corresponding actuators 202j-1.

In some embodiments, a control system 201m is used to maintain a desired polishing pad thickness profile by adjusting one or a combination of the rotational speed, sweep speed, and downforce of the conditioning disk 260. Here, the control system 201m includes the actuators 202j-1, a displacement sensor 203m coupled to the conditioner arm 262, and the system controller 28. The displacement sensor 203m is used to determine a thickness of the polishing pad 231 and a profile of the pad thickness in the radial direction thereacross. Here, the displacement sensor 203m is an inductive sensor which measures eddy currents to determine a distance between an end of the sensor 203m to the surface of the metal platen 228 disposed therebeneath. The thickness of the polishing pad 231 is determined using a difference between a known displacement when the pad conditioning disk 260 is in contact with the platen 228 and the displacement when the pad conditioning disk 260 is in contact with the polishing pad 231 mounted on the platen 228.

The system controller 28 compares a thickness profile of the polishing pad 231, determined using the displacement sensor 203m, to a target thickness profile to determine the difference therebetween. Based on the differences, the system controller 28 generates a conditioning recipe, i.e., a set of conditioning parameters, which may be used to drive the actual thickness profile of the polishing pad 231 towards the target thickness profile. In some embodiments, the generated conditioning recipe changes the dwell time of the conditioning disk 260 and/or a downforce on the conditioning disk at one or more radial locations. Dwell time refers to an average duration of time the conditioning disk 260 spends at a radial location as the conditioning disk 260 is swept from an inner radius to an outer radius of the polishing pad 231 as the platen 228 rotates to move the polishing pad 231 there beneath.

The pad cooling assembly 220 (FIG. 2C) is used to maintain the polishing surface of the polishing pad 231 within a desired range of temperatures or at a desired temperature set point. In a typical polishing process, chemical and mechanical activity at the polishing interface generates heat which in turn increases the temperature of the substrate 242 and polishing pad 231. Relatively high and/or unstable temperatures can result in undesirable removal rate variations across the surface of the substrate 242 (within-wafer non-uniformity) or from substrate to substrate (wafer-to-wafer non-uniformity). For many damascene processes, relatively high temperatures degrade the local planarization resulting in poor local planarity, erosion of the underlying layer, and/or dishing of trench, contact, via, or line features formed in the underlying layer. Therefore, herein the pad cooling assembly 220 is configured to cool surface of the polishing pad 231 by delivering a non-reactive coolant, e.g., flakes of solid phase carbon dioxide (carbon dioxide snow), thereunto. As the carbon dioxide snow sublimates (transitions from the solid to gas phase without passing through the intermediate liquid phase) heat is removed from the surface of the polishing pad 231 desirably reducing the overall temperature of the polishing process. Beneficially, sublimation of the carbon dioxide snow prevents undesirable dilution of the polishing fluid on the polishing pad. In other embodiments, the coolant comprises a cryogenic fluid, i.e., a fluid with boiling point at or below the threshold of 120 Kelvin, which is stored and delivered to the surface of the polishing pad 231 in liquid form, such as liquid oxygen (LOX), liquid hydrogen, liquid nitrogen (LIN), liquid helium, liquid argon (LAR), liquid neon, liquid krypton, liquid xenon, liquid methane, or combinations thereof.

The pad cooling assembly 220 includes a coolant delivery arm 275 positioned over the polishing pad 231, a plurality of nozzles 276 disposed on the coolant delivery arm 275, and a control system 201n. Here, the control system 201n includes a coolant source 202n, one or more sensors 203n, a controller 204n, and a control parameter sensor 205n. The one or more sensors 203n, e.g., IR sensor or pyrometers, are positioned to face the surface of the polishing pad 231 and are used to measure the temperature thereof. In some embodiments, one or more of the sensors 203n comprises a thermal imaging system which generates thermal images of the surface of the polishing pad 231.

The plurality of nozzles 276 are fluidly coupled to the coolant source 202n which provides vapor and solid carbon dioxide thereto. The plurality of nozzles 276 generate a carbon dioxide snow as the vapor carbon dioxide expands therethrough and deliver the carbon dioxide snow to the surface of the polishing pad 231. The controller 204n, in combination with the sensors 203n, maintains the temperature of the polishing pad 231 at a target value by adjusting a mass flowrate of carbon dioxide provided to the nozzles 276 from the coolant source 202n. Here, the control parameter(s) for controlling the temperature of the surface of the polishing pad 231 includes the mass flowrate, as measured by control parameter sensor 205n. In some embodiments, delivery and/or flowrate of the coolant to individual ones of the plurality of nozzles 276 is independently controlled. In those embodiments, the pad cooling assembly 220 may be used to adjust the temperature of regions of surface of the polishing pad 231 to maintain a desired uniformity of temperatures or distribution of temperatures thereacross.

Each of the control systems 201a-n of the polishing system 20 described above uses a closed-loop feedback control method to maintain one or more polishing parameters at or near respective target values by adjusting respective control parameters related thereto. As discussed above, differences in the control parameters between substrates (e.g., wafer-to-wafer (WTW)), during polishing of an individual substrate (e.g., with-in wafer (WIW)), or both likely indicates a disturbance or change in the polishing process. Such disturbances or changes in the polishing process are unlikely to be caused by changes in the polishing parameters which are maintained at or near target values using the control systems 201a-1. Instead, such disturbances or process changes are likely to occur at the polishing interface and include changes in the surface of the substrate 242, changes in the surface of the polishing pad 231, changes in the composition, properties, and/or volume of polishing fluids, and combinations thereof. Thus, in some embodiments, an AI algorithm 110 using an unsupervised learning model may be used to identify and understand patterns in the control parameter data 120 in order to better understand the complicated chemical and mechanical interactions between surfaces, fluids, and abrasives at the polishing interface.

As discussed in the methods below, in some embodiments, the AI algorithm 110 is trained to determine a functional relationship between one or more control parameters and in-situ substrate measurement data and to adjust a polishing fluid composition at the polishing interface based thereon. Thus, the fluid delivery system 216 herein is configured to stop flowing, start flowing, and/or adjust the flowrate of individual polishing fluid components to the surface of the polishing pad 231, and thus to the polishing interface, based on instructions received from the system controller 28. In some embodiments, the instructions are in the form of a software algorithm, e.g., the one or more machine learning AI models 112, generated using the trained AI algorithm 110.

The fluid delivery system 216 (FIG. 2C) is used to deliver polishing fluids, including individual fluid components, to the surface of the polishing pad. The fluid delivery system 216 includes a fluid distribution system 281, a delivery arm 282 comprising a plurality of nozzles 283, and an actuator 284 coupled to the fluid delivery arm 282. The fluid distribution system 281 is fluidly coupled to a plurality of polishing fluid sources 287a, 287b which deliver polishing fluids and/or fluid components thereto. The actuator 284 is operable swing the delivery arm 282 over the polishing pad to position the plurality of nozzles 283 in a desired radial dispense position thereover.

Here, the fluid distribution system 281 comprises one or a combination of a plurality of valves 285a, pumps 285b, and flow controllers 285c which may be used to control, measure, and deliver polishing fluids and/or individual polishing fluid components to the surface of the polishing pad 231, and a polishing fluid mixing apparatus 285d. In some embodiments, the fluid distribution system 281 further includes one or more heaters (not shown) used to heat an individual polishing fluid and/or one or more individual polishing fluid components before and/or concurrent with delivery of the fluid and/or the component to the surface of the polishing pad 231.

Here, one or more polishing fluids and individual polishing components are delivered from the fluid distribution system 281 to corresponding one of the plurality of nozzles 283 using a plurality of delivery lines 288 fluidly coupled therebetween. In some embodiments, the fluid distribution system 281 is configured to independently deliver one or more different polishing fluids and/or fluid components to different ones of the plurality of nozzles 283 and/or to independently control the flowrates of the different polishing fluids or fluid components thereunto. Thus, the fluid distribution system 281 may be used to provide a desired distribution of polishing fluid and/or individual polishing fluid components dispensed onto the surface of the polishing pad 231 in order to provide a desired polishing fluid compositional gradient across the surface of the polishing pad 231.

In some embodiments, the fluid distribution system 281 further includes a mixing apparatus 285d which may be used to adjust the composition of a polishing fluid by adding one or more polishing fluid components thereto before delivering the resulting mixture to the surface of the polishing pad 231. In some embodiments (not shown) the mixing station is disposed on the fluid delivery arm 282.

Examples of individual polishing fluid components which may be independently delivered to the surface of the polishing pad 231, to desired locations on the surface of the polishing pad, and/or added to a polishing fluid using the mixing apparatus 285d, include: abrasive solutions, having nanoscale silica, or metal oxide particles suspended therein; complexing agents; corrosion inhibitors; oxidizing agents; pH adjusters and/or buffers, polymeric additives, passivation agents, accelerators, surfactants, or combinations thereof.

In some embodiments, the fluid delivery system 216 further includes an optical sensor, such as a camera 299, positioned over the polishing pad 231 and facing theretowards. In some embodiments, the camera 299 is a digital camera (e.g., CCD camera) that is configured to generate a digital image or a stream of digital images of an object that it is positioned to view. The optical sensor may be used to determine a distribution of polishing fluid and/or polishing fluid components across the surface of the polishing pad 231. In some embodiments, one or more of the individual polishing fluids and/or individual polishing fluid components comprise an optical marker, such as a conventional water soluble dye or fluorophore. In those embodiments, images captured using the optical sensor may be analyzed to determine a distribution of a polishing fluid across the surface of the polishing pad 231 and/or to determine a compositional gradient of individual polishing fluid components across the surface of the polishing pad 231.

In some embodiments, the polishing fluid distribution and/or composition at the surface of the polishing pad 231 is adjusted, based on the analysis of the images, by starting, stopping, or changing the flowrate of one or more individual polishing fluid components to one or more of the individual nozzles 283. In some embodiments, the polishing fluid distribution and/or composition at the surface of the polishing pad 231 is continuously adjusted to a target distribution and/or composition using a closed-loop feedback control system 280. For example, here the control system 280 includes the system controller 28, the optical sensor (e.g., camera 299) which is used to determine the polishing fluid distribution and/or composition at the surface of the polishing pad 231, and the fluid distribution system 281. In another example, here the control system 280 includes the system controller 28, an electrochemical sensor (not shown) or pH sensor (not shown), which is used to determine the polishing fluid composition at the surface of the polishing pad 231 and/or within the fluid distribution system 281. Based on the analysis of images acquired from the optical sensor, the system controller 28 directs the fluid distribution system 281 to change one or more control parameters related to the delivery of polishing fluids and/or polishing fluid components to the surface of the polishing pad 231. For example, control parameters may include starting, stopping, or changing the flowrate of an individual polishing fluid and/or polishing fluid component provided to the collective plurality of nozzles 283 or to individual ones of the plurality of nozzles.

In some embodiments, one or more of the images captured using the optical sensor, such as a time-series of a plurality of the captured images, comprise process monitoring in-situ measurement data 122 which may be used as training data 111 for the AI algorithm 110 training methods provided herein.

The in-situ substrate monitoring system 222 (FIG. 2A) is used to monitor the thickness of a material layer on the substrate surface and/or to detect changes in the substrate surface as material is removed therefrom. Information collected using the in-situ substrate monitoring system 222 may be used as in-situ results data 124. Here, the in-situ substrate monitoring system 222 includes a controller 290 for one or both of an optical system 291 and an eddy current monitoring system 292. The optical system 291 includes a light source (not shown) and an optical sensor 289 respectively positioned to direct light towards the substrate 242 through a window (not shown) formed in the polishing pad 231 and to receive reflected light therefrom. The controller 290 analyzes the reflected light to determine one or more properties of the substrate surface therefrom. For example, the optical system 291 may be used to detect changes in the reflectance of the substrate surface, e.g., to determine the clearing of a metal layer from the substrate surface, to detect scattering of light reflected from the substrate surface, e.g., to determine changes in planarity of the substrate surface, and/or use interferometry techniques to determine a thickness of a transparent film, e.g., a dielectric layer, disposed on the substrate surface.

The eddy current monitoring system 292, includes an eddy current assembly 294 comprising an eddy current generator and sensor disposed in the surface of the platen 228. The eddy current monitoring system 292 uses eddy current assembly 294 induces and measures eddy currents in a conductive material layer, e.g., a metal layer, on the substrate and the current monitoring system determines a thickness of the conductive material layer therefrom. In some embodiments, the eddy current monitoring system 292 is used to determine a thickness profile across the radius of the substrate 242 as the substrate is swept thereabove.

In some embodiments, one or both of the optical system 291 and the eddy current monitoring system 292 are used in combination with an endpoint algorithm being executed on a controller of the polishing system, such as on the system controller 28, to trigger a change in polishing conditions based on the thickness of the material layer and/or the clearing of overburden material from the field surface of the underlying layer.

The system controller 28 is used to direct the operation of the polishing system 20 and the various components and subsystems thereof. In some embodiments, one or more or all of the functions of individual ones of the controllers 204a-n may be performed by the system controller 28. Herein the system controller 28 is operable in combination with the AI training platform 30 to implement the methods set forth herein. The system controller 28 includes a programmable central processing unit (CPU 295) which is operable with a memory 296 (e.g., non-volatile memory) and support circuits 297. For example, in some embodiments the CPU 295 is one of any form of general purpose computer processor used in an industrial setting, such as a programmable logic controller (PLC), for controlling various polishing system component and sub-processors. The memory 296, coupled to the CPU 295, is non-transitory and is typically one or more of readily available memory such as random access memory (RAM), read only memory (ROM), floppy disk drive, hard disk, or any other form of digital storage, local or remote. The support circuits 297 are conventionally coupled to the CPU 295 and comprise cache, clock circuits, input/output subsystems, power supplies, and the like, and combinations thereof coupled to the various components the polishing system 20, to facilitate control of a substrate polishing process.

Herein, the memory 296 is in the form of a computer-readable storage media containing instructions (e.g., non-volatile memory), that when executed by the CPU 295, facilitates the operation of the polishing system 200. Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. The instructions in the memory 296 are in the form of a program product such as a program that implements the methods of the present disclosure (e.g., middleware application, equipment software application etc.). In some embodiments, the disclosure may be implemented as a program product stored on a non-transitory computer-readable storage media for use with a computer system. Thus, the program(s) of the program product define functions of the embodiments (including the methods described herein).

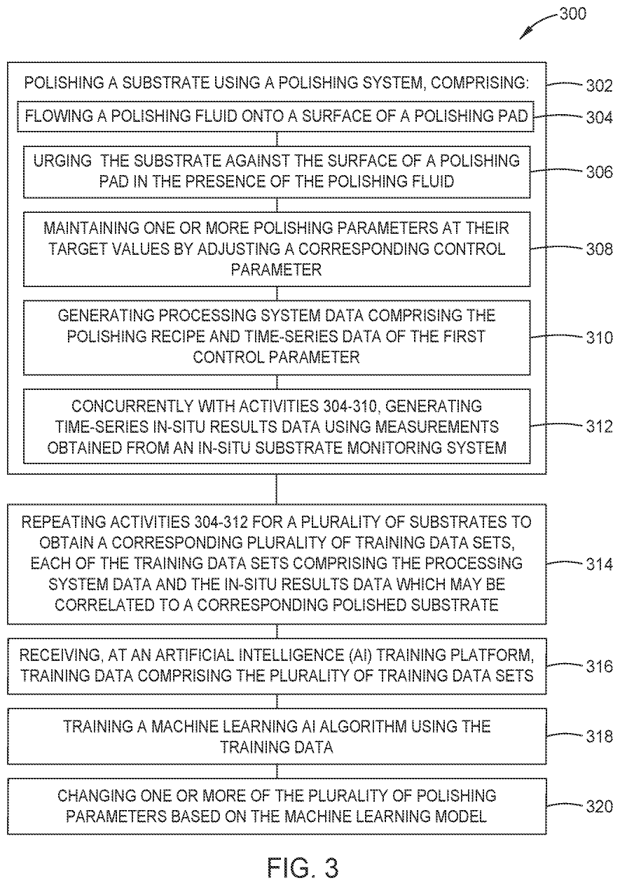

FIG. 3 is a diagram illustrating a method 300 of processing a substrate using the process improvement scheme 100 described in FIG. 1C. It is contemplated that at least portions of the method 300 may be performed on the polishing system 20 and may incorporate any of the features and functions thereof, including the individual control systems used therewith. Applications of the method 300 include, but are not limited to, bulk material planarization applications, such as interlayer dielectric (ILD) applications, and damascene polishing applications, such as shallow trench isolation applications (STI) and metal interconnect polishing applications.

At activity 302, the method 300 includes polishing a substrate using a polishing system, such as the polishing system 20 described above. Activity 302 will include a plurality of activities that include the activities 304-312.

At activity 304, the method 300 includes flowing a polishing fluid composition (e.g., slurry) onto a surface of a polishing pad in a polishing system 20, according to a polishing recipe. The flow rate and/or the amount of polishing fluid composition provided to a defined radial position on the surface of the polishing pad 231 can be controlled by use of commands sent from system controller 28 to the actuator 284 and/or fluid distribution system 281.

At activity 306, the method 300 includes urging the substrate against the surface of the polishing pad in the presence of the polishing fluid, according to the polishing recipe. Here, the polishing recipe is defined by a plurality of polishing parameters, including substrate carrier rotation speed, substrate carrier translation speed, platen rotation speed, substrate downforce, retaining ring downforce, polishing composition flow rate(s), rinsing solution flow rate(s) and pad conditioning parameters, and their corresponding target values. The target values include desired set points, values above desired lower thresholds, values below desired upper thresholds, and values between desired lower and upper thresholds. Activity 306 will include pressurizing one or more of the plurality of plenums 249 to cause the flexible membrane 248 in the substrate carrier to exert a force against a non-active (backside) surface of the substrate 242 to urge the front side surface against the polishing pad 231.

Target values may include a combination of fixed values, e.g., pre-determined set points or thresholds, and values determined by one or more software algorithms which are being executed on a controller of the polishing system before, after, and/or concurrently with the polishing process. For example, in some embodiments, the duration of a stage of a polishing sequence is determined using an endpoint algorithm executing on a controller of the polishing system. In some embodiments, one or more of the target values are determined by the trained AI algorithm 110, e.g., as part of an iterative continuous improvement process. In some embodiments, one or more of the target values are determined using a machine learning AI model 112 generated by the trained AI algorithm 110. In those embodiments, the machine learning AI model 112 may comprise a software algorithm being executed by the system controller 28 of the polishing system 20.

In a typical polishing process, a polishing recipe for a single substrate comprises a multi-stage polishing sequence, where one or more polishing parameter target values are changed for each stage of the sequence. In some embodiments, one or more stages of the multi-stage polishing sequence are performed at a first polishing station before the substrate is moved to a second polishing station, and sometimes moved again to a third polishing station, for performance of the remainder of the polishing sequence.

Examples of polishing parameters which may be used to define a polishing recipe include, but are not limited to: platen rotation speed; platen temperature; substrate carrier rotation speed; substrate carrier sweep speed; substrate carrier sweep start and stop positions (inner and outer radial positions on the polishing pad); substrate downforce (downward pressure exerted again the backside of the substrate); distribution of downforces across the substrate; retaining ring downforce (downward pressure exerted against the retaining ring); the difference between the substrate downforce and the retaining ring downforce; polishing pad surface temperature; polishing pad surface temperature uniformity and or distribution; polishing fluid and/or individual polishing fluid flowrates, including starting and stopping the flow of a polishing fluid or component; polishing fluid and/or individual polishing fluid component temperatures; polishing fluid composition either before delivery to the polishing pad, e.g., as an output from a polishing fluid mixing system, or on the surface of the polishing pad, e.g., as a result of the dispensing of individual polishing fluid components; and polishing fluid distribution and/or compositional gradient across the surface of the polishing pad, and duration (time).

Typically, the polishing recipe further includes processing parameters related to conditioning of the polishing pad before, after, and/or concurrently with the polishing process, herein pad conditioning parameters. Examples of pad conditioning parameters include: rotation speed of the conditioning disk, downforce exerted on the conditioning disk against the polishing pad, the dwell time of the conditioning disk over one or more portions of the polishing pad, and sweep speed of the conditioning disk across the surface of the polishing pad. As briefly discussed above, one or more of the pad conditioning parameters may be used along with a position sensor of the conditioner assembly to determine a conditioning disk dwell time. In some embodiments, the pad conditioning parameters can also include polishing pad thickness and/or a profile of the polishing pad thickness as measured from a location proximate to the center of the polishing pad to a location radially outward therefrom.

At activity 308, the method 300 includes maintaining one or more polishing parameters at or near their target values by adjusting respective control parameters corresponding thereto. Here, the one or more polishing parameters are maintained at or near their target values using a closed-loop control system. Thus, in some embodiments, maintaining a polishing parameter at or near its target value includes: (1) determining a difference between an actual value of the polishing parameter and its target value; (2) based on the determined difference, changing a control parameter of a control system corresponding to the polishing parameter; and (3) continuously repeating (1) and (2) to provide closed-loop control over the polishing parameter.

Control parameters, as used herein, include outputs from actuators and/or systems which cause a corresponding change in the actual value of the polishing parameter. Control parameters for a particular control system are different from the polishing parameter for that system. Although, as can be appreciated from the descriptions of at least some of the control systems herein, at least some of the parameters describe above as exemplary polishing parameters may serve as control parameters in a different control system. For example, in embodiments where the polishing pad thickness profile is used as a polishing parameter in a closed loop system, one or more of the individual parameters of conditioner downforce, rotation speed, and dwell times may be used as control parameters and adjusted to provide the desired pad thickness profile.

In some embodiments, at least one of the processing parameters of activity 308 comprises pad surface temperature and the corresponding control parameter comprises a mass flowrate of a coolant, e.g., carbon dioxide snow, delivered to the surface of the polishing pad. In some embodiments, the controller 204b, in combination with the sensor 203b, is used to control the temperature of the platen 228 at a target value by adjusting a flowrate of a coolant from the fluid source 202b through the one or more channels 234 in the polishing platen 228. In some embodiments, the control parameter(s) for controlling the temperature of the polishing platen 228 comprises the coolant flowrate measured by a flowmeter, e.g., the control parameter sensor 205b.

At activity 310, the method 300 includes generating processing system data 114. Here, the processing system data 114 includes the polishing recipe and time-series data of the first control parameter.

At activity 312, the method 300 includes, concurrently with activities 304 to 310, generating time-series in-situ results data using measurements obtained from an in-situ substrate monitoring system, such as the in-situ substrate monitoring system 222 described herein.

In some embodiments, at activity 312, a camera 299 (FIG. 2A), which is positioned to view the polishing surface (e.g., top surface) of the polishing pad 231, is configured to provide a signal (e.g., video signal stream) that is monitored and analyzed by one or more software algorithms running within the camera or the system controller 28 to detect a change in or variation in an optical property of the surface of the polishing pad and/or polishing fluid composition disposed thereon. In one example, the camera is an IR camera that is configured to detect gradients in temperature across the polishing pad surface and/or temperature variations over time. The software algorithm can be used to detect the temperature of and/or the variation in temperature on the surface of the polishing pad and/or polishing fluid composition disposed thereon in real time. The camera 299 and/or system on which the algorithm is running is then adapted to provide a signal, which includes time-series in-situ results data, to the system controller 28 and/or a signal that includes training data to the artificial intelligence (AI) training platform 30. Additionally, a flow rate sensing device and/or polishing fluid composition detecting device (e.g., pH sensor, abrasive particle concentration sensor) that are coupled to components within the fluid distribution system 281 can also be configured to deliver a signal regarding the amount of and/or the composition of one or more polishing fluid compositions that are being dispensed on the surface of the polishing pad while the camera is monitoring the surface of the polishing pad. The time-series in-situ results data, provided in the signal provided by the camera 299 and the flow rate sensing device and/or polishing fluid composition detecting device(s) is analyzed by the artificial intelligence (AI) training platform 30A during subsequent activities to detect an interaction between these different types of data and then in a subsequent activity cause a change in the temperature of the polishing pad using the components found in the pad cooling assembly 220 and/or the composition of the polishing fluid composition based on the data received over time.

In another example, at activity 312, the camera 299 (FIG. 2A) is configured to detect the state of the polishing pad surface, such as whether the polishing pad surface has a desired amount of “pad conditioning”. In this case, the camera 299 is positioned and configured to detect the amount roughness and/or asperities found on the polishing surface of the polishing pad to determine the state of the polishing pad surface. In some embodiments, the camera 299 is replaced by a profilometer or other device that is configured to detect and measure the degree of surface roughness. The surface roughness may be characterized by either an Rₐ, Rᵣₘₛ, R_{Sk}, or Rₚ value. The surface roughness detected by the camera, or similar device, may include irregularities in the pad material on the polishing surface of the polishing pad that are up-to about 10-50 microns in size. Additionally, a flow rate sensing device and/or polishing fluid composition detecting device (e.g., pH sensor, abrasive particle concentration sensor, etc.) may also be configured to deliver a signal regarding the amount of and/or the composition of a polishing fluid composition that is being dispensed on the surface of the polishing pad while the camera is monitoring the state of the polishing pad surface. The time-series in-situ results data, provided in the signal provided by the camera 299, or similar device, and the flow rate sensing device and/or polishing fluid composition detecting device can be used by the artificial intelligence (AI) training platform 30A and the system controller 28 to cause a conditioning process to occur, cause a change in the temperature of the polishing pad using the pad cooling assembly 220 and/or cause a change in the composition of the polishing fluid composition based on the detected interaction of the different types of data. The signals from these devices can be provided to the system controller 28 and/or a signal that includes training data can be delivered to the artificial intelligence (AI) training platform 30.

In another example, at activity 312, the camera 299 (FIG. 2A) is configured to detect the coverage and/or the flow of the polishing fluid across one or more regions of the polishing pad surface as it is being dispensed on to the polishing pad. In this case, the camera 299 is positioned and configured to detect the amount of spread of the polishing fluid across the polishing surface of the polishing pad to determine the state of one or more of the components in the fluid distribution system 281, such as detect obstructions in one or more of the nozzles 283, detect variations in the output of a fluid pump, and/or detect variations in the fluid delivery arm 282 position relative to a desired position over the polishing pad surface and/or relative to a position of the substrate carrier 238 over the polishing pad. The amount of the spread of the polishing fluid across the polishing surface of the polishing pad can be measured or determined by the coverage of a horizontal area of the polishing pad or a percentage of the field-of-view (FOV) of the camera 299. In some cases, the camera is also configured to detect gradients in temperature across the polishing pad surface and/or temperature variations over time. Additionally, a flow rate sensing device and/or polishing fluid composition detecting device (e.g., pH sensor, abrasive particle concentration sensor, etc.) may also be configured to deliver a signal regarding the amount of and/or the composition of a polishing fluid composition that is being dispensed on the surface of the polishing pad while the camera is monitoring the coverage and/or the flow of the polishing fluid across one or more regions of the polishing pad surface. The time-series in-situ results data, provided in the signals provided from the camera 299 and the flow rate sensing device and/or polishing fluid composition detecting device(s) can be used by the artificial intelligence (AI) training platform 30A and the system controller 28 to cause in a subsequent activity an adjustment in the position of the fluid delivery arm 282 to adjust the position at which the polishing fluid is delivered to the surface of the polishing pad, cause an increase in the flow of a polishing fluid out of one or more of the nozzles 283, cause a change in the temperature of the polishing pad using the pad cooling assembly 220 and/or cause a change in the composition of the polishing fluid composition based on the detected interaction of the different types of data during subsequent activities.

At activity 314, the method 300 includes repeating activities 304 to 312 for a plurality of substrates to obtain a corresponding plurality of training data sets. Here, each of the training data sets include processing system data and the in-situ results data which may be correlated to a corresponding polished substrate.

At activity 316, the method 300 includes receiving, at an artificial intelligence (AI) training platform 30, training data 111 comprising the plurality of training data sets. In some embodiments, the plurality of training data sets include data relating to a dispensed amount of slurry composition during a polishing process, the concentration of the dispensed slurry composition during the polishing process, the temperature of the polishing pad after the slurry composition is dispensed during the polishing process, polishing pad characteristics during a portion of the polishing process, and time between pad conditioning processes received over time from one or more polishing systems 20 to detect an interaction between the different data sets.

In one example, the plurality of training data sets that are collected and subsequently analyzed by the artificial intelligence (AI) training platform 30 includes the detection of trends in the polishing process results data, such as dishing, wafer-to-wafer non uniformity (WTWNU), planarization efficiency and local planarity, based on a detected interaction between data found in training data sets that include the detection of one or more polishing fluid composition compositions, the detection of differences between different polishing fluid composition compositions (e.g., use of different abrasives or amounts of one type of abrasive), the detection of a certain type of substrate (e.g., oxide polishing process or metal polishing process), the detection of a polishing fluid flow rate, and/or a detected trend in the temperature of the polishing pad during a plurality of polishing processes performed in one or more polishing systems 20.

In another example, at activity 316, the plurality of training data sets that are collected and subsequently analyzed by the artificial intelligence (AI) training platform 30 includes the detection of trends in an optical property of the surface of the polishing pad and/or polishing fluid composition disposed thereon, and a trend in a variation in one or more polishing fluid composition compositions, or differences between different polishing fluid composition compositions (e.g., use of different abrasives or amounts of one type of abrasive) on a certain type of substrate (e.g., oxide polishing process or metal polishing process).

In another example, at activity 316, the plurality of training data sets that are collected and subsequently analyzed by the artificial intelligence (AI) training platform 30 includes the detection in the coverage and/or the flow of the polishing fluid across one or more regions of the polishing pad surface, the detection of the polishing fluid flow rate, and/or a detected trend in the temperature of the polishing pad during a plurality of polishing processes performed in one or more polishing systems 20.

At activity 318, the method 300 includes generating a machine learning AI model 112 by training a machine learning AI algorithm 110 using the training data 111. During activity 318, the artificial intelligence (AI) training platform 30 can perform an analysis of currently received data from various sources using the machine learning AI model 112.

In one example, at activity 318, the artificial intelligence (AI) training platform 30 can determine, based on the receipt of data generated by the camera 299 and one or more polishing fluid composition detecting devices and the use of the machine learning AI model 112, that a detected trend in increasing pad polishing pad surface temperature can be caused by an increase in the concentration of abrasive particles in the polishing fluid composition or a reducing in dispensed polishing fluid. Based on prior and current analyses performed by the artificial intelligence (AI) training platform, the artificial intelligence (AI) training platform can determine that the detected trend in increasing pad polishing pad surface temperature is caused by the improper mixing of a batch of polishing fluid composition, or a drift in an dosing mechanism that is tasked with controlling the composition of the processing solution, based on similar prior detected excursions that occurred in one or more of the polishing systems 20.

In another example, the artificial intelligence (AI) training platform 30 can determine, based on the receipt of data generated by the camera 299 and one or more polishing fluid composition detecting devices and the use of the machine learning AI model 112, that a detected drift in an optical property of the surface of the polishing pad can be caused by a decreased effectiveness of a pad conditioning disk (e.g., disk is wearing out), based on similar prior detected trends in one or more of the polishing systems 20.

As discussed above, in another example, the artificial intelligence (AI) training platform 30 can determine, based on the receipt of data generated by the camera 299 and other relevant sensors and the use of the machine learning AI model 112, that a detected change in the fluid coverage over one or more regions of the surface of the polishing pad can be caused by an obstructions in one or more of the nozzles 283, a variation in the output of a fluid pump, and/or a variation in the fluid delivery arm 282 position relative to a desired position over the polishing pad surface, based on similar prior detected trends in one or more of the polishing systems 20.

At activity 320, the method 300 includes changing one or more of the plurality of polishing parameters in a processing recipe based on an analysis performed using the machine learning AI model 112 during activity 318. In one example, the one or more polishing parameters that are changed based on the analysis performed by the AI algorithm can include adjusting a dispensed amount of slurry composition during a current polishing process or a future polishing process, adjust the concentration of the dispensed slurry composition during the current polishing process or a future polishing process, adjust the temperature of the polishing pad after the slurry composition is dispensed during the current polishing process or a future polishing process, and/or cause a pad conditioning process to be started or stopped. The one or more of the plurality of polishing parameters that are changed may also be implemented on one polishing system 20 or a plurality of polishing systems 20 based on the analysis performed by the AI algorithm by use of a system controller 28 or Fab production control system 40, respectively.

In one example, in the case where there is a detected trend in increasing pad polishing pad surface temperature is caused by the improper mixing of a batch of polishing fluid composition, or a drift in a polishing fluid component dosing mechanism that is tasked with controlling the composition of the processing solution, the artificial intelligence (AI) training platform 30 can instruct the system controller 28, or user by use of graphical-user-interface (GUI) connected to the system controller 28, to replace the polishing fluid composition or the dosing mechanism and/or adjust one or more processing variables in the polishing process recipe being run on the current or future substrates processed in the polishing system 20.

In another example, in the case where there is a detected drift in an optical property of the surface of the polishing pad is caused by a decreased effectiveness of a pad conditioning disk, the artificial intelligence (AI) training platform 30 can instruct the system controller 28, or user by use of a GUI connected to the system controller 28, to replace the pad conditioning disk, adjust the conditioning disk dwell time on certain portions of the polishing pad and/or adjust one or more processing variables in the polishing process recipe being run on the current or future substrates processed in the polishing system 20.

As discussed above, in another example, in the case where there is a detected drift in the coverage and/or the flow of the polishing fluid across one or more regions of the polishing pad surface, the artificial intelligence (AI) training platform 30 can instruct the system controller 28 to adjust the position of the fluid delivery arm 282 to adjust the position at which the polishing fluid is delivered to the surface of the polishing pad, cause an increase in the flow of a polishing fluid out of one or more of the nozzles 283, cause a change in the temperature of the polishing pad using the pad cooling assembly 220, cause a change in the composition of the polishing fluid composition delivered from one or more of the nozzles 283, and/or adjust one or more processing variables in the polishing process recipe being run on the current or future substrates processed in the polishing system 20.

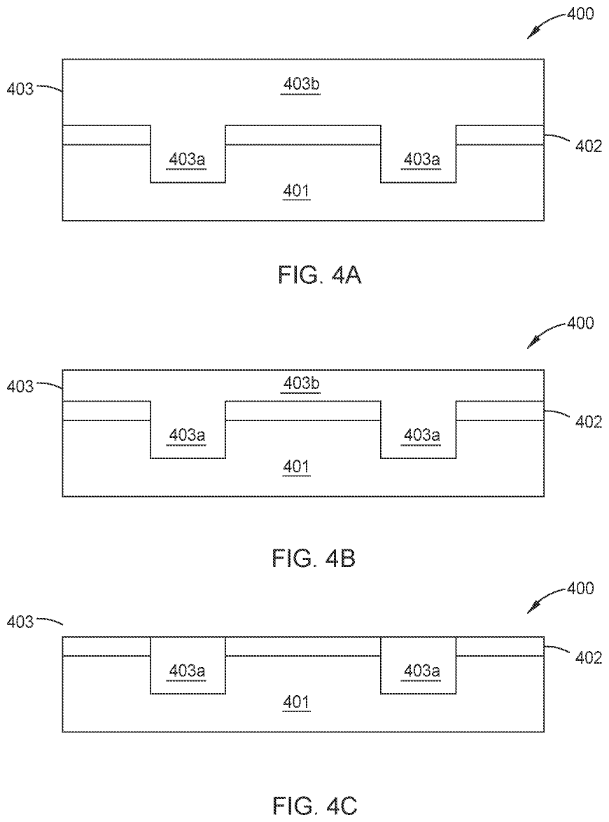

In some embodiments, the method 300 includes removing an overburden of material from a surface of a substrate, such as schematically illustrated in FIGS. 4A-4C. FIG. 4A illustrates the substrate 400 prior to the polishing process, the substrate 400 comprises one or more material layers 401, 402, e.g., an epitaxial (Si) layer and a silicon nitride (SiN) layer disposed thereon. A plurality of openings are formed in the one or more material layers 401, 402 to form a patterned surface. A fill material layer 403, e.g., an oxide layer (SiO2) is deposited onto the patterned surface to fill the plurality of openings. The fill material disposed in the openings forms a plurality of features 403a, such as shallow trench isolation features and an overburden layer 403b of the fill material layer 403 remains to be removed with the polishing process.

FIG. 4B illustrates the partial removal of the overburden layer 403b using the polishing process and FIG. 4C illustrates the complete removal of the overburden layer 403b and the desirably planar features 403a remaining in the patterned surface.

Typically, changes in the surface of the substrate 400 as the overburden layer 403b of fill material is removed (cleared) therefrom are detectable in the time-series data generated using the in-situ substrate monitoring system 222. In some embodiments, such changes are detected using an endpoint algorithm being executed on a controller of the polishing system. The endpoint algorithm triggers a change in the polishing process as the overburden of material clears from the field surface of the substrate in an STI or metal damascene processes. Unfortunately, such reactive endpoint detection schemes may result in over polishing of the substrate surface causing undesirable dishing and erosion of the features in the surface thereof.

In some embodiments the AI algorithm 110 is trained to recognize a functional relationship between the time-series in-situ results data 124 and the processing system data 114, such as individual or combined time-series data for the one or more control parameters. The functional relationship may be used by the trained AI algorithm 110 and/or the generated machine learning AI model 112 to predict time horizon of a polishing endpoint before the overburden of material begins to clear from the substrate surface instead of concurrently therewith. Based on the predicted time horizon, the polishing fluid composition may be changed at the surface of the polishing pad in order to provide better local planarization performance.

In some embodiments, changing one or more of the plurality of polishing parameters based on the machine learning AI model 112 at activity 318 includes changing a composition of the polishing fluid disposed on the surface of the polishing pad based on the functional relationship. In some embodiments, changing the composition of the polishing fluid includes starting, stopping, or changing the flowrate of an individual polishing fluid component delivered to the surface of the polishing pad.

In some embodiments, the training data 111 used to train the machine learning AI algorithm 110 further includes any portions or combinations of the substrate tracking data 128, facilities systems data 130, and electrical test data 132 as previously described in FIGS. 1B and 1C.

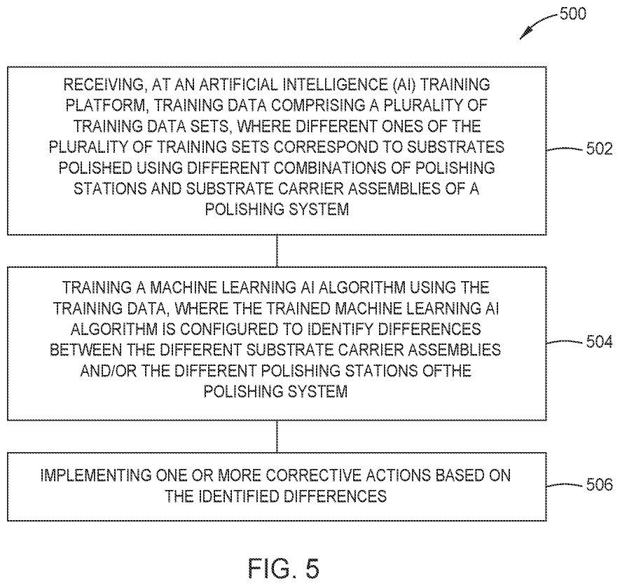

FIG. 5 is a diagram illustrating a method 500 of matching polishing performance between polishing systems.

At activity 502, the method 500 includes receiving, at an artificial intelligence (AI) training platform 30, training data comprising a plurality of training data sets. Here, different ones of the plurality of training data sets corresponds to substrates polished using different combinations of polishing stations and substrate carrier assemblies of a polishing system. Each of the training data sets comprises processing system data correlated to each of the substrates polished using the polishing system.

Here, each of the training data sets includes processing system data 114 comprising polishing recipe data 118 and control parameter data 120. The polishing recipes data 118 includes a plurality of polishing parameters and a plurality of target values corresponding thereto. The control parameter data 120 incudes time-series data of control parameters of one or more closed-loop control systems. The one or more closed loop control systems are used to maintain corresponding polishing parameters at or near their target values.

At activity 504, the method 500 includes training a machine learning AI algorithm using the training data. Here, the trained machine learning AI algorithm is configured to identify differences between the different substrate carrier assemblies and/or the different polishing stations of the polishing system.

At activity 506, the method 500 includes implementing one or more corrective actions based on the identified differences.

In some embodiments, the method 500 is used to identify differences between different substrate carrier assemblies and/or different polishing stations across a plurality of polishing systems and implement one or more corrective actions based thereon.

Beneficially, the machine learning AI systems and AI algorithm training methods set forth herein may be used to better understand and take advantage of the combined capabilities of apparatus and subsystems of advanced CMP processing systems resulting in improved polishing results, desirably wider process windows, and improved polishing system processing uniformity.

While the foregoing is directed to embodiments of the present disclosure, other and further embodiments of the disclosure may be devised without departing from the basic scope thereof, and the scope thereof is determined by the claims that follow.

1. A computer-implemented method of polishing substrates, comprising:
polishing a substrate using a polishing system, comprising:
(a) flowing a polishing fluid onto a surface of a polishing pad, according to a polishing recipe, the polishing recipe comprising a plurality of polishing parameters and a corresponding plurality of target values;
(b) urging a substrate against the surface of the polishing pad according to the polishing recipe;
(c) maintaining, by adjusting a first control parameter, a first polishing parameter of the plurality of polishing parameters at or near its target value;
(d) generating processing system data comprising the polishing recipe and time-series data of the first control parameter; and
(e) concurrently with (a)-(d), generating time-series in-situ results data using measurements obtained from an in-situ substrate monitoring system;
repeating (a)-(e) for a plurality of substrates to obtain a corresponding plurality of training data sets, each of the training data sets comprising the processing system data and the in-situ results data for a polished substrate;
receiving, at an artificial intelligence (AI) training platform, training data comprising the plurality of training data sets, wherein at least a portion of the plurality of training data sets are received sequentially in time; and
changing one or more of the plurality of polishing parameters based on an analysis of the received training data performed by a machine learning AI algorithm.

2. The method of claim 1, wherein the target values comprise desired set points, values above a desired lower threshold, values below a desired upper threshold, and/or values between desired the lower and upper thresholds for each of the polishing parameters.

3. The method of claim 1, wherein
the in-situ results data comprises data derived from a signal provided from a camera that is positioned to view and is configured to detect a variation in temperature of at least a portion of the surface of the polishing pad.

4. The method of claim 3, wherein
the first polishing parameter comprises a temperature of the surface of the polishing pad, and
the first control parameter comprises a flow rate of a coolant delivered to the surface of the polishing pad or a flow rate of a polishing fluid delivered to the surface of the polishing pad.

5. The method of claim 1, wherein the in-situ results data comprises:
data derived from a signal provided from a camera that is positioned to detect a position at which the polishing fluid is dispensed on the surface of the polishing pad, or
data derived from a signal provided from a camera that is positioned to detect an amount of coverage of the polishing fluid dispensed on the surface of the polishing pad from a polishing fluid delivery nozzle.

6. The method of claim 5, wherein the first control parameter comprises:
a flow rate of a polishing fluid delivered to the surface of the polishing pad, or
a position of the polishing fluid delivery nozzle relative to the surface of the polishing pad.

7. The method of claim 1, wherein the in-situ results data comprises:
data derived from a signal provided from a camera that is positioned to detect a temperature of at least a portion of the surface of the polishing pad, and
data derived from a signal provided from a sensor that is configured to detect a composition of polishing fluid.

8. The method of claim 7, wherein
the first polishing parameter comprises a temperature of the surface of the polishing pad, and
the first control parameter comprises a flow rate of a coolant delivered to the surface of the polishing pad or a flow rate of a polishing fluid delivered to the surface of the polishing pad.

9. The method of claim 1, wherein
the in-situ results data comprises data derived from a signal provided from a camera that is positioned to detect a roughness of the surface of the polishing pad, or positioned to detect an optical property of the surface of the polishing pad,
the first polishing parameter comprises a pad conditioning parameter of the surface of the polishing pad, and
the first control parameter comprises a rotation speed of a conditioning disk, a downforce exerted on the conditioning disk against the polishing pad, a dwell time of the conditioning disk over one or more portions of the surface of the polishing pad, or a sweep speed of the conditioning disk across the surface of the polishing pad.

10. The method of claim 1, wherein maintaining the first polishing parameter at or near its target value comprises:
i determining a difference between an actual value of the first polishing parameter and its target value;
ii. based on the determined difference, changing the first control parameter of a first control system; and
iii. continuously repeating i. and ii. to provide closed-loop control over the first polishing parameter.

11. The method of claim 10, wherein the first polishing parameter comprises a temperature of the surface of the polishing pad.

12. The method of claim 11, wherein
the polishing fluid comprises a slurry composition, and
the first control parameter comprises a flow rate or an amount of the slurry composition delivered to the surface of the polishing pad.

13. The method of claim 12, wherein the first control parameter comprises a flow rate of a coolant delivered to the surface of the polishing pad.

14. The method of claim 10, wherein the changing one or more of the plurality of polishing parameters based on the analysis of the received training data performed by the machine learning AI algorithm further comprises training a machine learning AI algorithm using the training data, and wherein
the trained machine learning AI algorithm identifies a functional relationship between the time-series in-situ results data and the time-series data for the first control parameter, and
changing one or more of the plurality of polishing parameters includes changing a composition of the polishing fluid disposed on the surface of the polishing pad based on the functional relationship.

15. The method of claim 14, wherein changing the composition of the polishing fluid includes starting, stopping, or changing a flowrate of an individual polishing fluid component delivered to the surface of the polishing pad.

16. The method of claim 1, wherein the training data used to train the machine learning AI algorithm further comprises one or a combination of:
substrate tracking data comprising processing histories of one or more of the plurality of substrates and/or information related to devices formed thereon;
facilities system data comprising information generated using one or more facilities supply systems including analytical information of polishing fluids delivered to the polishing system from a remote polishing fluid distribution system; and
electrical test data comprising electrical test information generated from one or more of the plurality of substrates at a post-polishing electrical test measurement operation.

17. A computer-implemented method of matching polishing performance between polishing systems, comprising:
receiving, at an artificial intelligence (AI) training platform, training data comprising a plurality of training data sets, wherein
each of the training data sets comprises processing system data correlated to individual ones of a first plurality of substrates polished using a first polishing system,
different ones of the first plurality of substrates are polished using different combinations of substrate carrier assemblies from a plurality of substrate carrier assemblies and polishing stations from a plurality of polishing stations of the first polishing system, and
the processing system data for each of the training data sets comprises:
a polishing recipe comprising a plurality of polishing parameters and a corresponding plurality of target values, wherein one or more of the plurality of polishing parameters are maintained at or near their target value using corresponding closed-loop control system; and
time-series data of control parameters of the closed-loop control systems; and
training a machine learning AI algorithm using the training data, wherein the trained machine learning AI algorithm is configured to identify differences between the different combinations of substrate carrier assemblies or the different polishing stations of the first polishing system; and
implementing one or more corrective actions based on the identified differences.

18. The computer-implemented method of claim 17, wherein
the plurality of training data sets further comprises processing system data correlated to individual ones of a second plurality of substrates polished using a second polishing system,
different ones of the second plurality of substrates are polished using different combinations of substrate carrier assemblies from a plurality of substrate carrier assemblies and polishing stations from a plurality of polishing stations of the second polishing system,
the trained machine learning AI algorithm is configured to identify differences between the different combinations of substrate carrier assemblies and/or the different polishing stations of the first and second polishing systems; and
implementing one or more corrective actions based on the identified differences.

19. The computer-implemented method of claim 18, wherein each the training data sets of the plurality of training data sets further comprises time-series in-situ results data obtained from in-situ substrate monitoring systems corresponding to the pluralities of polishing stations of the first and second polishing systems.

20. The computer-implemented method of claim 19, wherein the in-situ substrate monitoring systems comprise a camera that is positioned to view and is configured to detect a variation in temperature of at least a portion of a surface of a polishing pad disposed within the first polishing system.
